(19) United States
(12) Patent Application Publication
(10) Pub. No.: US 2012/0299089 A1
(43) Pub. Date: Nov. 29, 2012

(54) Semiconductor Device and Method for Manufacturing the same

(76) Inventors: Zhijiong Luo, Poughkeepsie, NY (US); Haizhou Yin, Poughkeepsie, NY (US); Huilong Zhu, Poughkeepsie, NY (US)

(21) Appl. No.: 13/377,729

(22) PCT Filed: Aug. 9, 2011
(86) PCT No.: PCT/CN11/01312

§ 371 Date: Dec. 12, 2011

(30) Foreign Application Priority Data
May 24, 2011 (CN) 201110137573.5

(51) Int. Cl. H01L 21/28; H01L 29/78

(52) U.S. Cl. 257/330; 438/589; 257/E29.262; 257/E21.191; 257/E21.207

(57) ABSTRACT

It is disclosed a semiconductor device and a method for manufacturing the same. One method comprises providing a semiconductor layer that is formed on an insulating layer; forming a mask pattern on the semiconductor layer, which exposes a portion of the semiconductor layer; removing the exposed portion of the semiconductor layer of a predetermined thickness, thereby forming a groove; forming a gate stack in the mask pattern and the groove; removing the mask pattern to expose a portion of sidewalls of the gate stack. The method not only meets the requirement for a precise thickness of the SOI, but also increases the thickness of the source/drain regions as compared to a device having a uniform SOI thickness at the gate stack, thereby facilitating a reduction of the parasitic resistance of the source/drain regions.

### CROSS REFERENCE

This application is a Section 371 National Stage Application of, and claims priority to, International Application No. PCT/CN2011/001312, filed on Aug. 9, 2011, which claims priority to Chinese Application No. 201110137573.5 filed on May 24, 2011. Both the PCT application and the Chinese application are incorporated herein by reference in their entireties.

### FIELD OF THE INVENTION

The present invention generally relates to the field of semiconductor manufacture, in particular to semiconductor device and method for manufacturing the same.

### BACKGROUND OF THE INVENTION

The main characteristic of an SOI (Silicon on Insulator) structure is in that a buried oxide layer is interposed between the SOI and the bulk silicon to break the electrical connection therebetween. Wherein the bulk silicon layer is thick, which mainly functions to provide mechanical support for the buried oxide layer and SOI thereon. A SOI device differs from a common semiconductor device mainly in that the common semiconductor device is fabricated on a bulk silicon or an epitaxial layer on the bulk silicon, the semiconductor device is electrically connected directly with the bulk silicon, and the separation between the high and low voltage units and between the SOI and the bulk silicon is realized through a reverse biased PN junction; while in the SOI device, the SOI and the bulk silicon and even the high and low voltage units are completely separated through an insulating medium, and the electrical connections between the respective components are completely removed. Such a structural characteristic results in many advantages for the SOI device, such as little parasitic effect, fast speed, low power consumption, high integration, and strong anti-radiation ability.

In the architecture of a full depleted transistor, the effect of the component is closely related to the thickness of the SOI. In order to make sure that all the components have parameter similarity, the thickness of the SOI must be strictly controlled. However, the thickness of a super-thin SOI can hardly be controlled, and a thin source/drain regions has a very high parasitic resistance.

### SUMMARY OF THE INVENTION

In view of the above problem, the present invention provides a method for manufacturing a semiconductor device, wherein said method comprises:

providing a semiconductor layer on an insulating layer;
forming a mask pattern on the semiconductor layer, the mask pattern exposes a portion of the semiconductor layer;
removing the exposed portion of the semiconductor layer of a predetermined thickness, thereby forming a groove;
forming a gate stack in the mask pattern and the groove; and
removing the mask pattern to expose a portion of sidewalls of the gate stack.

The present invention also provides a semiconductor device, which comprises:

a semiconductor layer formed on an insulating layer; and
a gate stack, a portion of said gate stack being embedded into the semiconductor layer, and a portion of the semiconductor layer being sandwiched between said gate stack and the insulating layer.

By means of the method provided by the present invention, a thick SOI that can be easily controlled can be formed first, so that a groove is formed on a portion of the thick SOI, then a gate stack is formed in the groove; besides, a process that can be easily controlled may be employed to form an SOI that is thin at the gate stack but thick at the source/drain regions, thus not only meeting the requirement on the precision of the thickness of the SOI, but also correspondingly increasing the thickness of the source/drain regions as compared to the device having uniform SOI thickness at the gate stack, thereby facilitating a reduction of the parasitic resistance at the source/drain regions.

### DESCRIPTION OF THE DRAWINGS

FIG. 1 is a flow chart of the method for manufacturing a semiconductor device according to an embodiment of the present invention;

FIGS. 2-12 are schematic cross-sectional views of different stages of manufacturing the semiconductor device according to an embodiment of the present invention.

### DETAILED DESCRIPTION OF THE INVENTION

The following disclosure provides many different embodiments or examples for realizing different structures of the present invention. To simplify the disclosure of the present invention, components and configurations of specific examples are described in the following; they are merely examples and are not intended to limit the present invention. In addition, reference numbers and/or letters can be repeated in different embodiments in the present invention for the purpose of concision and clarity, which in itself does not indicate the relationship between the various embodiments and/or configurations that are discussed. The present invention provides examples of various specific processes and materials, but substitution of other processes and/or other materials may be occurred to those skilled in the art.

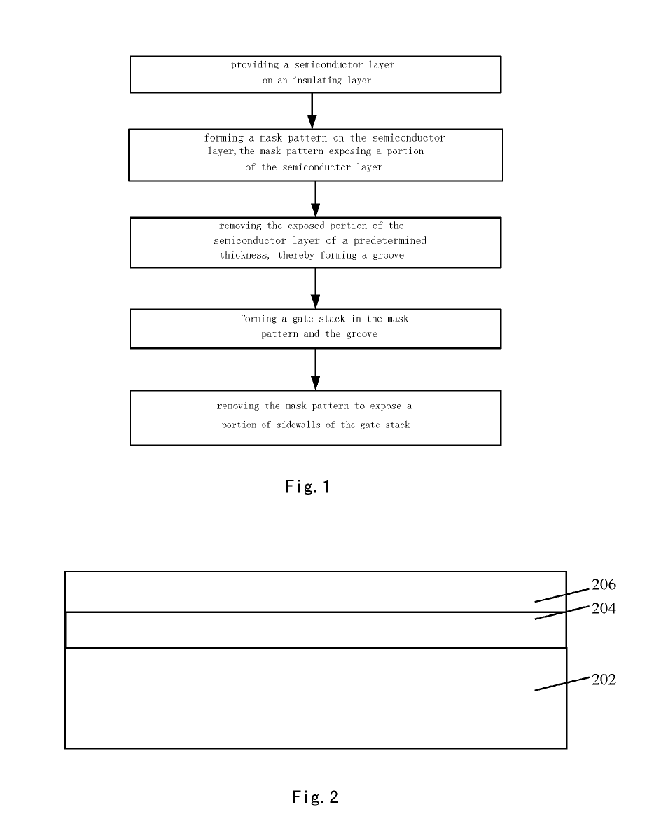

Reference is made to FIG. 1 and FIG. 2. First, a semiconductor layer 206 is provided on an insulating layer 204. The insulating layer 204 is located on a semiconductor substrate 202. Namely, the semiconductor layer 206, insulating layer 204 and semiconductor substrate 202 form an SOI substrate. In this embodiment, the material for the semiconductor layer 206 is Si, while in other embodiments, the material for the semiconductor layer 206 may also be other appropriate semiconductor material such as Ge or SiGe. The insulating layer 204 may be of such insulating material as silicon oxide or silicon oxynitride. The semiconductor substrate 202 may include Si or Ge substrate or the like. In other embodiments, the semiconductor substrate 202 may also be any semiconductor material layer formed on other substrates (such as glass), or it may even be a III-V group compound semiconductor (e.g. GaAs, InP, etc.) or a II-VI group compound semiconductor (e.g. ZnSe, ZnS) or the like.

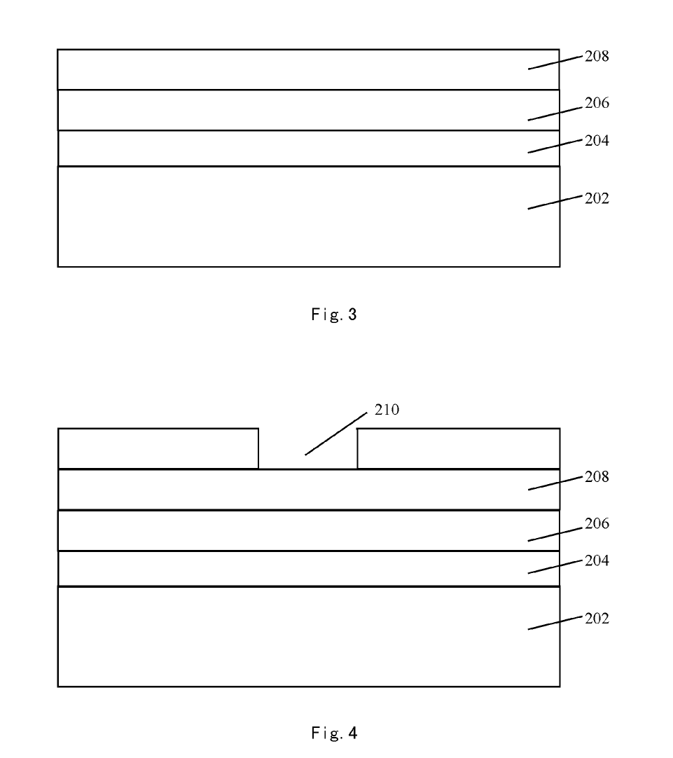

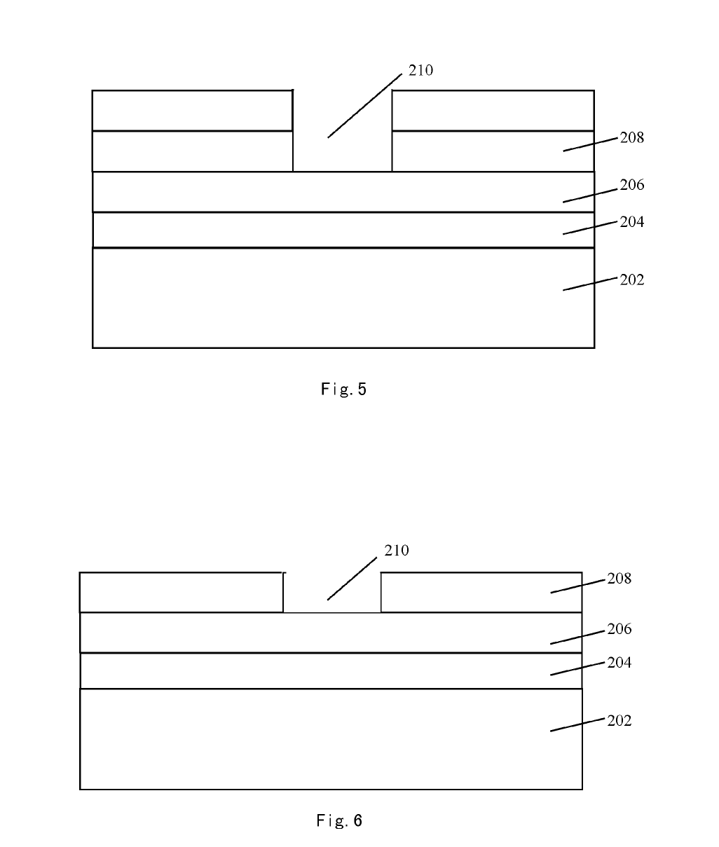

Afterwards, a mask pattern 208 is formed on the semiconductor layer 206, and the mask pattern 208 exposes a portion of the semiconductor layer 206. In this embodiment, the material for the mask pattern 208 may be silicon oxide, silicon oxynitride and/or silicon nitride, or it may also be photoresist. The above are merely examples, but the invention is not limited to these. The specific process can be seen in FIGS. 3-6. First, a mask layer 208 is formed on the semiconductor layer 206, as shown in FIG. 3. Then the mask layer 208 is covered by a photoresist that is patterned to form an opening pattern 210 as shown in FIG. 4. Next, the mask layer 208 is etched through the opening pattern 210 to expose a portion of the semiconductor layer 206, as shown in FIG. 5. Subsequently, the photoresist on the mask layer 208 is removed to form the mask pattern 208 as shown in FIG. 6.

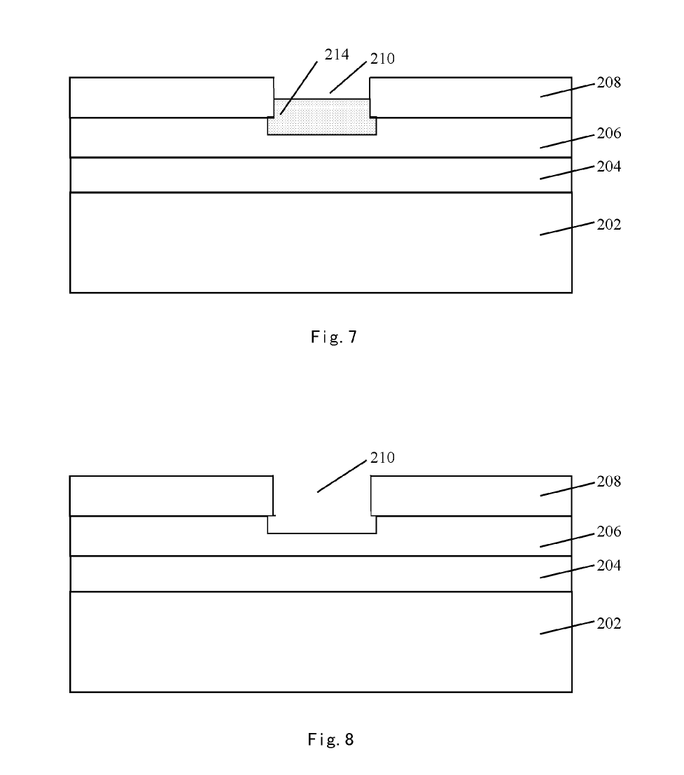

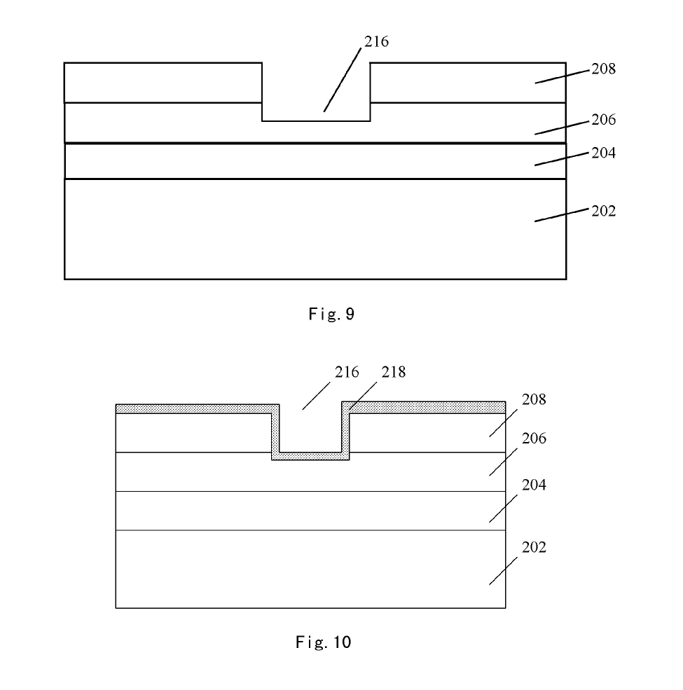

Then, the exposed portion of the semiconductor layer 206 is removed of a predetermined thickness, thereby forming a groove 216. Specifically, a portion of a surface of the exposed semiconductor layer 206 is transformed into a heterogeneous layer 214 through the opening pattern 210, as shown in FIG. 7; then the heterogeneous layer 214 is removed to form the groove 216, so that the exposed portion of the semiconductor layer 206 has a thickness less than 50 nm, as shown in FIGS. 8 and 9. After forming the groove 216, a height difference is formed between an upper surface of the unexposed portion of the semiconductor layer 206 and an upper surface of the exposed portion of the semiconductor layer 206, which is greater than or equal to 3 nm, such as 5 nm, 8 nm, 10 nm or 15 nm.

The heterogeneous layer may be formed by either one of the following two methods: one is a thermal oxidation method, i.e. a thermal oxidation is performed on the structure so that the surface of the semiconductor layer 206 under the opening pattern 210 is transformed into a oxide layer as the heterogeneous layer 214; the other is an ion implantation method, i.e. an ion implementation is performed to implant ion into a portion of a surface of the exposed semiconductor layer 206, then an annealing process is performed to transform the portion of the surface, into which ions are implanted, into a heterogeneous layer. In the embodiment of the present invention, the implanted ion is oxygen ion.

The step of removing the heterogeneous layer 214 includes performing wet etching or dry etching to form an opening embedded into the semiconductor layer 206 of the SOI substrate, as shown in FIG. 8. Said step preferably also includes performing micro-etching to the opening pattern 210 of the mask layer 208 to form a substantially square groove 216 running through the mask pattern 208 as shown in FIG. 9.

Then, a gate stack is formed in the mask pattern 208 and the groove 216. Specifically, the semiconductor structure as shown in FIG. 9 may be covered by a gate dielectric layer 218, as shown in FIG. 10. Said gate dielectric layer 218 may be formed by Chemical Vapor Deposition (CVD) or Atomic Layer Deposition (ALD). The material for the gate dielectric layer 218 may be silicon oxide, or a high-k material such as HfO₂, HfSiO, HfSiON, HfTaO, HfSiO, HfZrO, Al₂O₃, La₂O₃, ZrO₂ or LaAlO, or combinations thereof. In addition, the gate dielectric layer may also be formed by a thermal oxidation process, but the gate dielectric layer is only formed on the surface of the semiconductor layer exposed by the groove, and it is not formed on the sidewalls of the mask layer 208 (not shown in the figure).

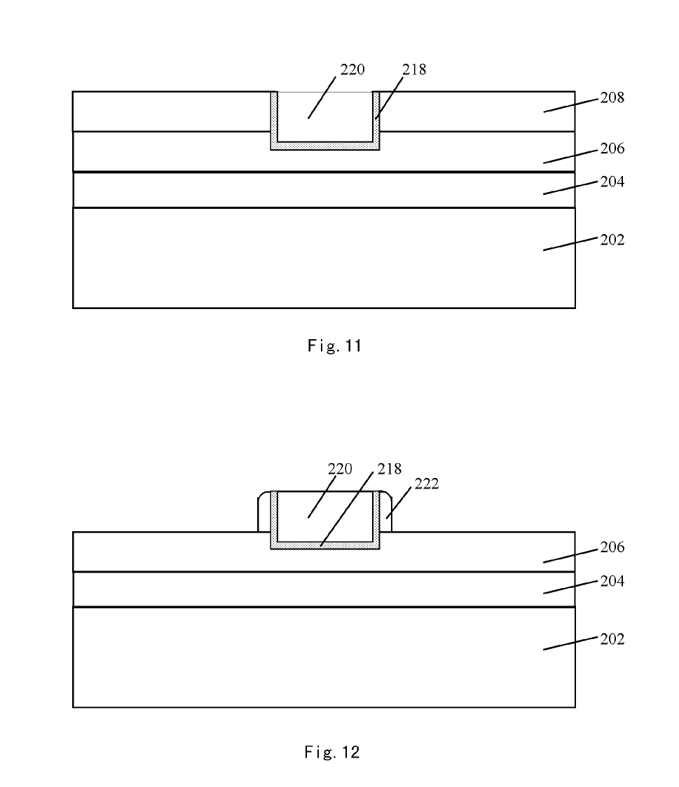

Afterwards, a gate electrode layer 220 is formed on the gate dielectric layer 218, and a planarization operation (such as CMP) is performed to remove the gate dielectric layer 218 and gate electrode layer 220 outside the groove 216, thereby obtaining the structure as shown in FIG. 11. The gate electrode layer 220 may be a one-layer or multi-layer structure. When the gate electrode layer 220 is a multi-layer structure, it may include a work function metal layer and a primary metal layer, wherein the work function metal layer may be deposited by at least one element selected from a group consisting of: MoNx, TiSiN, TiCN, TaAlC, TiAlN, TaN, PtSix, Ni₃Si, Pt, Ru, Ir, Mo, HfRu and RuOx for PMOS; by an element selected from a group consisting of TaC, TiN, TaTbN, TaErN, TaYbN, TaSiN, HfSiN, MoSiN, RuTax and NiTax, or combinations thereof, for NMOS. The primary metal layer may be polysilicon, Ti, Co, Ni, Al, W, alloy, or metal silicide. The deposition of the gate dielectric layer 218 and the gate electrode layer 220 may be performed by conventional deposition processes, such as sputtering, Physical Vapor Deposition (PVD), Metal Organic Compound Chemical Vapor Deposition (MOCVD), Atomic Layer Deposition (ALD), Plasma Enhanced Atomic Layer Deposition (PEALD) or other appropriate methods. Then, said device is planarized by means of a Chemical Mechanical Polishing (CMP) technique.

Finally, the mask pattern 208 is removed to expose a portion of sidewalls of the gate stack. The mask pattern 208 may be removed by means of dry etching or wet etching technique. After removing said mask pattern, there is preferably the step of forming a spacer 222 on the exposed portion of the sidewalls, as shown in FIG. 12. Wherein, the spacer 222 may be a one-layer or multi-layer structure as desired (and the materials for two adjacent layers may be different), while the present invention does not have any restriction in this regard.

So far, the semiconductor device as shown in FIG. 12 is formed, which comprises: a semiconductor layer 206 formed on an insulating layer 204; a gate stack (including a gate dielectric layer 218 and a gate electrode layer 220 in the embodiment of the present invention), a portion of the gate stack being embedded into the semiconductor layer 206, and a portion of the semiconductor layer being sandwiched between said gate stack and the insulating layer 204. Wherein, the material of the semiconductor layer 206 may be one of Si, SiGe and Ge, or any other materials mentioned previously. The material of the semiconductor layer sandwiched between the gate stack embedded into the semiconductor layer 206 and the insulating layer 204 may have a thickness less than 50 nm. There is a height difference between an upper surface of the semiconductor layer 206 that does not carry the gate stack and an upper surface of the semiconductor layer 206 that carries the gate stack, which is greater than or equal to 3 nm, such as 5 nm, 8 nm, 10 nm or 15 nm. In the embodiment of the present invention, preferably a spacer 222 is formed on the sidewalls of the gate stack, and the spacer 222 surrounds a portion of the sidewalls of the gate stack that is higher than the semiconductor layer 206, that is, the portion of the sidewalls of the gate stack surrounded by the spacer 222 is higher than the semiconductor layer 206. It shall be noted that said spacer 222 can be either adjacent to the sidewalls of the gate electrode layer 220 or to the sidewalls of the gate dielectric layer 218.

By means of the method provided by the present invention, a thick SOI that can be easily controlled can be formed first, so that a groove is formed at a portion of said thick SOI, then a gate stack is formed in said groove; besides, a process that can be easily controlled may be employed to form an SOI that is thin at the gate stack but thick at the source/drain regions, thus not only meeting the requirement on the precision of the thickness of the SOI, but also correspondingly increasing the thickness of the source/drain regions as compared to the device having uniform SOI thickness at the gate stack, thereby facilitating a reduction of the parasitic resistance for the source/drain regions.

Although the embodiments and the advantages have been described in detail, it shall be understood that various changes, substitutions and modification can be made to these embodiments within departing from the spirit of the present invention and the protection scope defined in the appended claims. As for other examples, those skilled in the art shall readily understand that the sequence of the process steps may vary without changing the protection scope of the present invention.

In addition, the scope to which the present invention is applied is not limited to the process, mechanism, manufacture, material composition, means, methods and steps described in the specific embodiments in the description. Those skilled in the art would readily appreciate from the disclosure of the present invention that the process, mechanism, manufacture, material composition, means, methods and steps currently existing or to be developed in the future, which perform substantially the same functions or achieve substantially the same effect as that in the corresponding embodiments described in the present invention, may be applied according to the present invention. Therefore, the appended claims of the present invention intend to include such process, mechanism, manufacture, material composition, means, methods or steps in the protection scope thereof.

What is claimed is:

1. A method for manufacturing a semiconductor device, comprising:
providing a semiconductor layer on an insulating layer;
forming a mask pattern on the semiconductor layer, the mask pattern exposing a portion of the semiconductor layer;
removing the exposed portion of the semiconductor layer of a predetermined thickness, thereby forming a groove;
forming a gate stack in the mask pattern and the groove; and
removing the mask pattern to expose a portion of sidewalls of the gate stack.

2. The method according to claim 1, wherein the step of removing the exposed portion of the semiconductor layer of a predetermined thickness comprises:
transforming a portion of a surface of the exposed semiconductor layer into a heterogeneous layer; and
removing the heterogeneous layer.

3. The method according to claim 2, wherein the heterogeneous layer is formed by a thermal oxidation process.

4. The method according to claim 1, wherein the step of removing the exposed portion of the semiconductor layer of a predetermined thickness comprises:
performing an ion implantation to implant ions into a portion of a surface of the exposed semiconductor layer;
performing an annealing process to transform the portion of the surface, into which ions are implanted, into a heterogeneous layer; and
removing the heterogeneous layer.

5. The method according to claim 4, wherein the implanted ions are oxygen ions.

6. The method according to claim 1, wherein the predetermined thickness is greater than or equal to 3 nm.

7. The method according to claim 1, wherein after removing the exposed portion of the semiconductor layer of a predetermined thickness, the exposed portion of the semiconductor layer has a thickness of less than 50 nm.

8. The method according to claim 1, wherein the step of forming the gate stack comprises:
forming a gate dielectric layer to cover sidewalls and bottom of the groove;
forming a gate electrode layer on the gate dielectric layer to fill the mask pattern and the groove; and
planarizing the gate electrode layer to expose the mask pattern.

9. The method according to claim 8, wherein the gate dielectric layer also covers sidewalls of the mask pattern.

10. The method according to claim 1, wherein the material of the semiconductor layer is Si, SiGe or Ge.

11. The method according to claim 8, further comprising forming a spacer on the exposed portion of the sidewalls of the gate electrode layer after removing the mask pattern.

12. The method according to claim 9, further comprising forming a spacer on an exposed portion of the sidewalls of the gate dielectric layer after removing the mask pattern.

13. A semiconductor device, comprising:
a semiconductor layer formed on an insulating layer; and
a gate stack, a portion of said gate stack being embedded into the semiconductor layer, and a portion of the semiconductor layer being sandwiched between said gate stack and the insulating layer.

14. The semiconductor device according to claim 13, wherein a height difference between an upper surface of the semiconductor layer carrying the gate stack and an upper surface of other portions of the semiconductor layer not carrying the gate stack is greater than or equal to 3 nm.

15. The semiconductor device according to claim 13, wherein the portion of the semiconductor layer sandwiched between the gate stack, which is embedded into the semiconductor layer, and the insulating layer has a thickness less than 50 nm.

16. The semiconductor device according to claim 13, wherein the material of the semiconductor layer is Si, SiGe or Ge.

17. The semiconductor device according to claim 13, wherein the portion of the gate stack embedded into the semiconductor layer comprises a gate dielectric layer and a gate electrode layer, the gate dielectric layer being sandwiched between the gate electrode layer and the semiconductor layer, and the rest portion of the gate stack is the gate electrode layer; or, the rest portion of the gate stack is the gate dielectric layer and the gate electrode layer, the gate dielectric layer surrounding the gate electrode layer.

18. The semiconductor device according to claim 17, further comprising a spacer, wherein, when the rest of the gate stack is the gate electrode layer, the spacer surrounds sidewalls of the gate electrode layer; and when the rest of the gate stack is the gate dielectric layer and the gate electrode layer, the spacer surrounds the gate dielectric layer in the rest portion of the gate stack.
